(19) United States
(12) Patent Application Publication
(10) Pub. No.: US 2003/0169094 A1
(43) Pub. Date: Sep. 11, 2003

(54) Exponential current source to linearize an output power control profile of a power amplifier

(76) Inventors: Yucai Zhang, Ottawa (CA); Wei An, Nepean (CA)

Correspondence Address: FREEDMAN & ASSOCIATES, 117 CENTREPOINTE DRIVE, SUITE 350, NEPEAN, ONTARIO, K2G 5X3, CA

(21) Appl. No.: 10/093,541

(22) Filed: Mar. 11, 2002

(51) Int. Cl. H03K 3/42

(52) U.S. Cl. 327/513

(57) ABSTRACT

The power control profile of a power amplifier circuit has improved linearity by supplying an exponential current source. The current source is an exponent function of the control voltage. There is obtained improved linearity of the power output vs control voltage profile for the power amplifier circuit. Advantageously, the exponential current source provides for a temperature compensated power amplifier circuit as well as the circuit having improved performance for variations in a power supply voltage.

### FIELD OF THE INVENTION

This invention relates to the area of current sources and more specifically to the area of current sources for biasing of power amplifiers.

### BACKGROUND OF THE INVENTION

In most communication systems like Bluetooth™, Wireless LAN, and CDMA, one key task is to control transmit power provided by a transmitter in order to decrease system electrical power consumption and to increase transmitter efficiency. For instance, through the use of power control circuitry, current of power amplifiers can be reduced when a lower output power level is required.

The output power, Pout, of most power amplifiers is set by an external control voltage Vctl, but the relation between Vctl and Pout is often nonlinear and influenced by temperature, supply voltage, input power, etc. The nonlinear relation between Pout and Vctl and associated variation due to temperature and supply voltage cause difficulty in designing a suitable control loop for the amplifier in order to maintain it's stability. Designing a linear power amplifier while compensating for supply voltage and temperature effects is one of the critical issues for power amplifier design. Current sources used to bias power amplifiers are known in the art. These current sources are coupled to amplification stages within power amplifiers in order to control their performance.

Prior Art U.S. Pat. No. 5,923,217 discloses an amplifier circuit and a method for generating a bias voltage for the amplifier circuit. Unfortunately, this prior art reference does not disclose temperature stability or power supply fluctuation stability for the amplifier circuit. It would be advantageous to have a power amplifier circuit which has a highly linear output power versus control voltage for variations in ambient temperature and amplifier power supply voltage.

It is therefore an object of the invention to provide a current source for a power amplifier circuit such a highly linear output power control profile is realized by the power amplifier circuit, even when power amplifier supply voltage as well as power amplifier circuit temperature vary.

### SUMMARY OF THE INVENTION

In accordance with the invention there is provided a power amplifier circuit comprising:

a control port for receiving a control voltage;

an exponential current source for receiving the control voltage and for generating a bias current such that the main bias current is related to the control voltage in an exponential manner; and,

an amplifying stage having a bias port coupled to the exponential current source for receiving the main bias current, an input port for receiving an input signal, and an output port for providing an amplified version of the input signal in dependence upon the bias current;

wherein the amplified version of the input signal, specified using a logarithmic scale, is approximately linearly proportional to the control voltage.

In accordance with an aspect of the invention there is provided an exponential current source comprising:

a control port for receiving a control voltage;

a power supply input port for receiving a power supply voltage;

a voltage reference source coupled to the power supply input port for receiving the power supply voltage and for providing a reference voltage;

a voltage divider circuit coupled to the control port for receiving the control voltage and for transforming the control voltage into a control current; and,

an inverse Widlar current mirror for receiving the control current and the voltage reference voltage, and for generating a main bias current provided to the amplifying stage bias port,

wherein the main bias current is related to the control voltage in an exponential manner and where the main bias current is independent of power supply fluctuations.

In accordance with another aspect of the invention there is provided a method of controlling a power amplifier circuit in response to a control voltage applied to a control input port, comprising the steps of:

providing a control voltage;

generating a main bias current exponentially related to the control voltage; and

providing the main bias current to the power amplifier circuit for approximately linearizing a relationship between an amplified signal provided from the power amplifier and the control voltage.

In accordance with yet another aspect of the invention there is provided a method of temperature compensating an amplifier comprising the steps of:

providing a plurality of resistors within the amplifier circuit for each having varied performance in response to changes in temperature; and

varying a main bias current provided to the amplifier in dependence upon changes in temperature due to some of the plurality of resistors, such that changes in amplifier performance and in the main bias current are varied for resulting in little or no change to an amplified version of the input signal in response to changes in temperature.

### BRIEF DESCRIPTION OF THE DRAWINGS

The invention will now be described with reference to the following drawings, in which:

FIG. 1, illustrates a Prior Art current source for biasing within power amplifier circuit;

FIG. 2, illustrates gain curves for Pₒᵤₜ vs V_{ctl} for the prior art circuit shown in Prior Art FIG. 1;

FIG. 3, illustrates a schematic circuit diagram according to the present invention;

FIGS. 4a and 4b are simulation results with exponential current source; with V_{ctl} varying with temperature, and V_{ctl} varying with V_{cc}; and,

FIGS. 5a and 5b are simulation curves showing Pₒᵤₜ vs V_{ctl} profiles, with variations in temperatures and power supply.

### DETAILED DESCRIPTION OF THE INVENTION

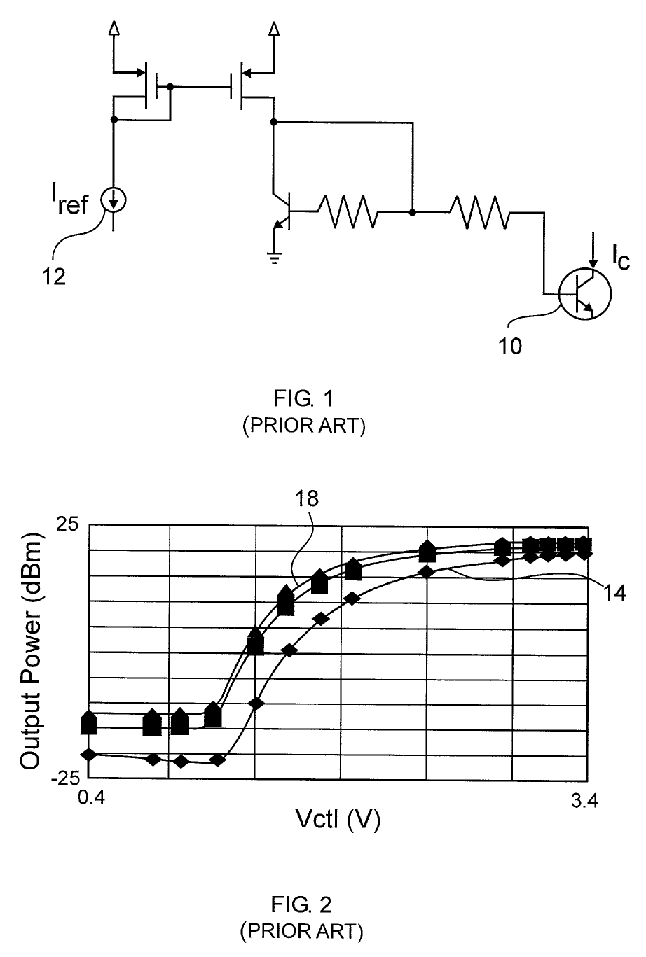

In Prior Art FIG. 1, a prior art amplifier circuit using a current source 12, to drive a base of a power transistor 10, is shown. The current source I_{ref}, 12, provides a reference current for the main bias circuit of the bipolar power amplifier. In the prior art, the current source 12 is a linear function of a control voltage, V_{ctl}, signal that is used to control the base of the power transistor 10 in such a manner that the output power, Pₒᵤₜ, of the power amplifier is varied by changing current provided by the current source 12. In Prior Art FIG. 2, a typical Pₒᵤₜ vs V_{ctl} profile of the prior art amplifier circuit is shown. In this example Pₒᵤₜ(dBm) is not linear with V_{ctl} and Pₒᵤₜ varies as temperature changes. Output power curve 18 results from a temperature of 80 degrees Celsius and output power curve 14 results from a temperature of −40 degrees Celsius.

In accordance with the present invention an exponential reference current source (I_{ref}) for providing a main bias current to a bipolar amplifier circuit is provided. Conventionally, I_{ref} is a linear function of the control voltage (V_{ctl}) signal that controls the output power (Pₒᵤₜ), in dBm, of the power amplifier circuit through changing I_{ref}.

With reference to Prior Art FIG. 1, a current source 12 is redesigned according to the invention to provide a reference current I_{ref} proportional to the exponent function of V_{ctl}, where:

I_{ref}α exp(V_{ctl})

and the Pₒᵤₜ vs V_{ctl} profile is linearized as:

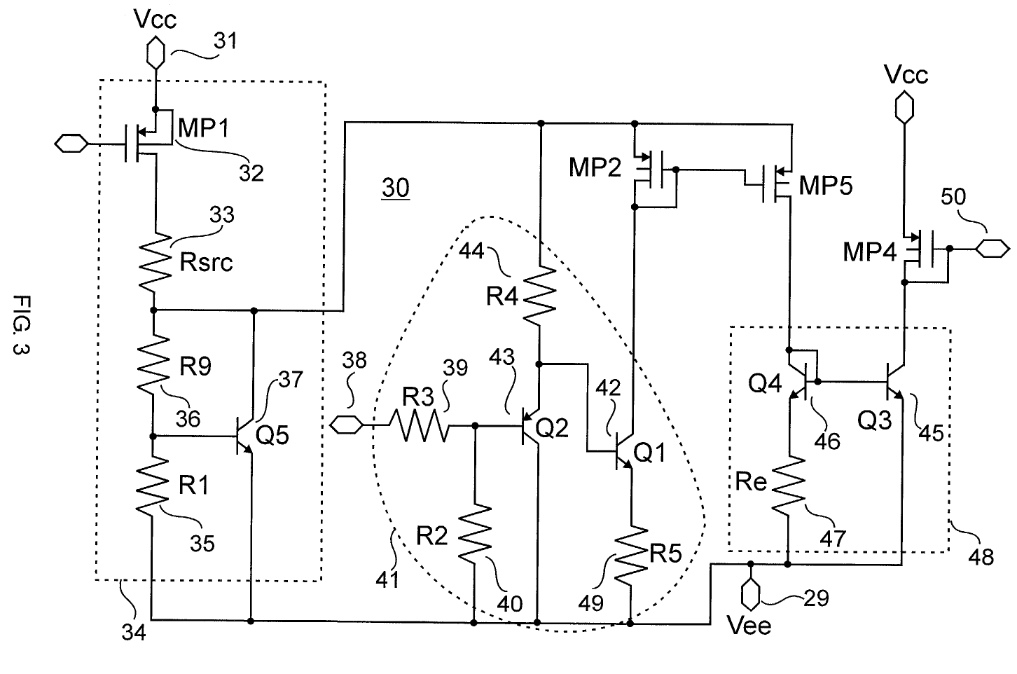

Pₒᵤₜ(dBm)α ln(I_{ref})=ln(exp(V_{ctl}))=V_{ctl}.

Whereby taking a natural logarithm of an exponential creates the linear relationship Pₒᵤₜ(dBm) α V_{ctl}. FIG. 3, illustrates a schematic diagram of an exponential current source (ECS) 30 which satisfies the linear relationship of Pₒᵤₜ(dBm) α V_{ctl}, a when this current source is applied to the base of the power transistor 10.

A power supply is coupled to a positive input port 31, V_{cc}, of the ECS 30, and additionally to the ground port 29, Vₑₑ. The positive input port 31 is coupled to a MOS transistor MP1 32, where a port of the MOS transistor MP1 32 is coupled in series to a source resistor 33, Rsrc. Resistors R9 36 and R1 35 form a voltage divider and are disposed in parallel with Q5 37. The components, MP1, Rsrc, Q5, R9 and R1 comprise a voltage reference source 34 within the ECS in order to reduce I_{ref} variation with power supply V_{cc} variations. The voltage reference source provides a reference voltage, V_{ref}, according to the following relation:

V_{ref}=(1+R₉/R₁)*V_{be}

By choosing proper types and values for components R9 36, R1 35 and Q5 37, temperature variation of the reference voltage are optimized.

The control voltage V_{ctl} is applied to a control voltage input port 38, where resistors R2 40 and R3 39 form a voltage divider for the control signal received at the control voltage input port 38.

A voltage-current converter 41 comprises components Q₁ 42, Q₂ 43, R₃ 39, R₄ 44, and R_{S} 49 which, in use, generate an output current I₁:

I₁=[V_{ctl}*R₂/(R₂+R₃)+V_{be2}−V_{be1}]/R_{S}

where V_{be2} and V_{be1} are derived from transistors Q2 and Q1 respectively.

On the right side, Q₃ 45 Q₄ 46 and Rₑ 47 form an inverse Widlar current mirror 48, Katsuji Kimura, “Low Voltage Techniques for Bias Circuits,” IEEE Trans. Circuit and

Systems-1: Fundamental Theory and Applications, Vol.44, NO.5, May 1997, incorporated herein by reference. In use the Widlar current mirror 48, generates the reference current I_{ref}, where:

I_{ref}=I₁*exp(I₁*Rₑ/Vₜ)

where,

Vₜ=kT/q

Since I₁ is proportional to V_{ctl}, I_{ref} is then proportional to exp(V_{ctl}). The reference current I_{ref} is provided via a reference current output port 50. Choosing an appropriate set of values for R_{S} 49, R4 44, Rₑ 47, Q₁ 42, and Q₂ 43 performs temperature compensation within the ECS, with proper temperature coefficients for the resistors and transistors.

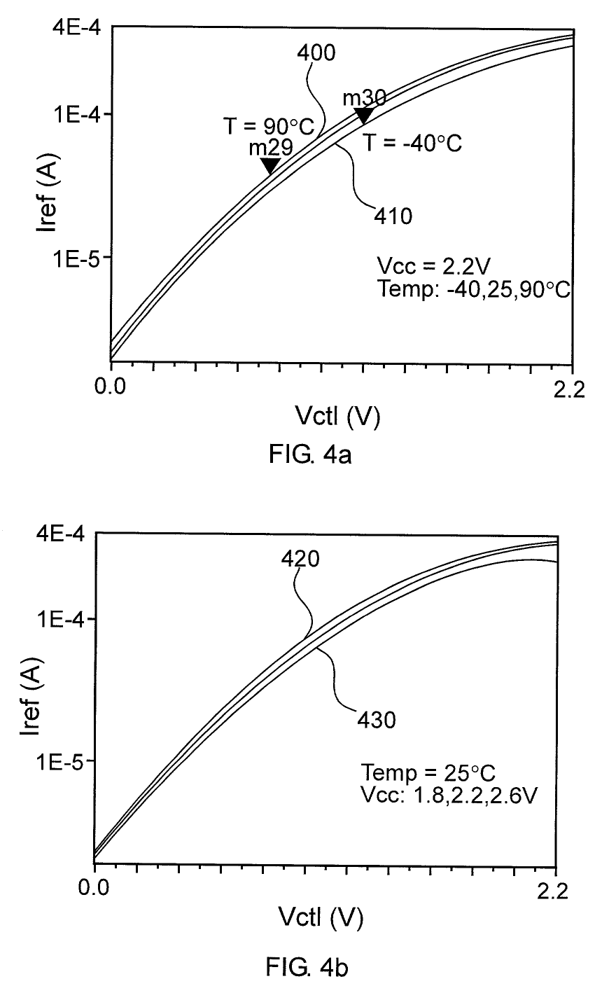

In FIG. 4a, a graph of I_{ref} vs V_{ctl} is shown for three different operating temperatures: −40 degrees C. 410, 25 degrees C. and 90 degrees C. 400, for a V_{cc} voltage of 2.2V. From this graph it can be seen that the three curves are almost identical in shape, but are shifted in current as a result of the temperature variation. At −40 degrees C. 410, the curve provides a lowest reference current ref but as the temperature increases to 90 degrees C. 400, the amount of reference current increases. The reference current I_{ref} for a given V_{cc} voltage is proportional to absolute temperature (PTAT). As the absolute temperature varies so will an amount of current provided by the ECS when driving the power transistor 10. The amount of current provided serves to linearize the power amplifier output when temperature changes.

FIG. 4b, illustrates how I_{ref} vs V_{ctl} varies for different V_{cc} voltages while temperature is kept constant at 25 degrees C. V_{cc} is varied from 1.8V, curve 430, to 2.6V, curve 420, where from the graph it is evident that the three curves are very close to each other, indicating small I_{ref} variations for a varying V_{cc}. This graph is indicative of how variations in the supply voltage have a minimal effect on the ECS which provides the reference current to the amplifier. Such that if amplifier circuit power supply fluctuations are present they will have a decreased effect on power amplifier output signal linearity.

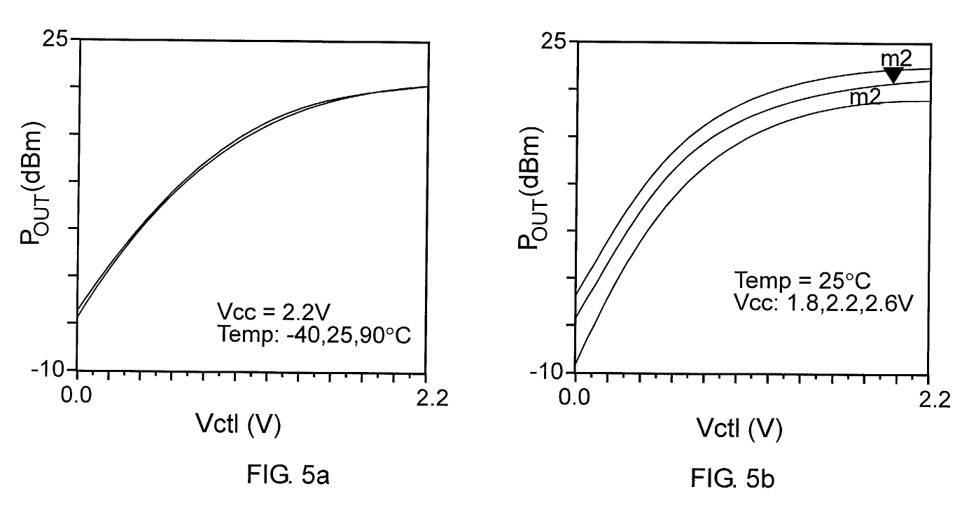

FIGS. 5a and 5b illustrate output power of the power amplifier circuit when the ECS is used to drive the base of the power transistor 10. FIG. 5a shows how Pₒᵤₜ vs V_{ctl} curves vary when ambient temperature of circuit is varied from −40 degrees C. to 90 degrees C., while maintaining V_{cc} fixed at 2.2V. In FIG. 5b, a relationship between Pout and V_{ctl} is plotted for variations in the supply voltage V_{cc}, while keeping ambient temperature constant at 25 degrees C. From this graph it is evident that as V_{cc} varies, the resulting curves are almost identical in shape, but are shifted in output power. In both cases input power applied to the power amplifier circuit is −4 dBm. In comparison to Prior Art FIG. 2, it is evident that the Pₒᵤₜ vs V_{ctl} curves that are obtained according to the present invention are more linear than that provided by the prior art as well as providing improved temperature and power supply variation performance.

Thus, the invention provides an exponential current source (ECS) that provides a reference current proportional to the exponent function of the control voltage. As a result this provides an improved linearity of the operating curves or profiles for a power amplifier circuit, where temperature variations and power amplification variations with respect to variations in the power supply are minimized.

Of course, instead of providing an ECS, values provided by the ECS can be stored in a lookup table, where within the lookup table a relationship is provided between the control voltage and data derived from the reference current. Such that, in use, a control voltage is compared to control voltage data stored in the lookup table. At a memory location referenced by the comparison, bias signal data is found, where the bias signal applied to the amplifier circuit is derived from the bias signal data stored within the lookup table. In this manner the bias current is applied to the amplifier circuit and as a result the output power is linearly proportional to the control voltage when sufficient values for the bias signal data are provided within the lookup table.

Having improved power amplifier temperature stability as well as improved performance for power supply fluctuations results in the power amplifier circuit useful for amplifying radio frequency signals, such as those used in BlueTooth™, Wireless LAN, and CDMA applications.

Numerous other embodiments may be envisaged without departing from the spirit or scope of the invention.

What is claimed is:

1. A power amplifier circuit comprising:
a control port for receiving a control voltage;
an exponential current source for receiving the control voltage and for generating a bias current such that the main bias current is related to the control voltage in an exponential manner; and,
an amplifying stage having a bias port coupled to the exponential current source for receiving the main bias current, an input port for receiving an input signal, and an output port for providing an amplified version of the input signal in dependence upon the bias current;
wherein the amplified version of the input signal, specified using a logarithmic scale, is approximately linearly proportional to the control voltage.

2. A power amplifier circuit according to claim 1, wherein an electrical power of the amplified version of the input signal specified using a logarithmic scale is proportional to the control voltage.

3. A power amplifier circuit according to claim 2, comprising:
a lookup table;
where within the lookup table a relationship is stored between the control voltage and data derived from the bias current.

4. A power amplifier circuit according to claim 1, wherein the exponential current source comprises:
a voltage reference source for receiving a power supply voltage and for providing a reference voltage;
a voltage divider circuit for receiving the control voltage and for transforming the control voltage into a control current; and,
an inverse Widlar current mirror for receiving the control current and the reference voltage, and for generating the main bias current provided to the amplifying stage bias port.

5. A power amplifier circuit according to claim 4, wherein the exponential current source comprises:
a resistor network, and
a transistor network;
wherein values and types of resistors within the resistor network, as well as sizes and types of transistors within the transistor network, are chosen in such a manner that the amplified version of the input signal is approximately temperature independent.

6. A power amplifier circuit according to claim 5, wherein the control current, I₁, generated by the voltage divider circuit is according to the following relation:
I₁=[V_{ctl}*R₂/(R₂+R₃)+V_{be2}−V_{be1}]/Rₛ
wherein V_{be2} and V_{be1} are derived from transistors within the transistor network, resistors R₂, R₃, and Rₛ, are found in the resistor network, and V_{ctl} is the control voltage.

7. A power amplifier circuit according to claim 5, wherein the power amplifier circuit is formed in an integrated circuit integrated on a common substrate.

8. A power amplifier circuit according to claim 7, wherein the integrated circuit comprises silicon and germanium.

9. A power amplifier circuit according to claim 5, wherein at least a transistor within the transistor network is a metal oxide semiconductor transistor.

10. A power amplifier circuit according to claim 5, wherein at least a transistor within the transistor network is a BJT transistor.

11. An exponential current source comprising:
a control port for receiving a control voltage;
a power supply input port for receiving a power supply voltage;
a voltage reference source coupled to the power supply input port for receiving the power supply voltage and for providing a reference voltage;
a voltage divider circuit coupled to the control port for receiving the control voltage and for transforming the control voltage into a control current; and,
an inverse Widlar current mirror for receiving the control current and the voltage reference voltage, and for generating a main bias current provided to the amplifying stage bias port,
wherein the main bias current is related to the control voltage in an exponential manner and where the main bias current is independent of power supply fluctuations.

12. An exponential current source according to claim 11, wherein the exponential current source comprises:
a resistor network;
a transistor network,
wherein values and types of resistors within the resistor network, as well as sizes and types of transistors within the transistor network, are chosen in such a manner that the amplified version of the input signal is approximately temperature independent.

13. An exponential current source according to claim 12, wherein the exponential current source is formed in an integrated circuit.

14. An exponential current source according to claim 13, wherein the integrated circuit comprises silicon and germanium.

15. An exponential current source according to claim 14, wherein at least a transistor within the transistor network is a metal oxide semiconductor transistor.

16. A power amplifier circuit according to claim 14, wherein at least a transistor within the transistor network is a BJT transistor.

17. A method of controlling a power amplifier circuit in response to a control voltage applied to a control input port, comprising the steps of:
providing a control voltage;
generating a main bias current exponentially related to the control voltage;
providing the main bias current to the power amplifier circuit for approximately linearizing a relationship between an amplified signal provided from the power amplifier and the control voltage.

18. A method of controlling a power amplifier circuit according to claim 17, wherein the amplified signal is substantially stable for variations in temperature.

19. A method of controlling a power amplifier circuit according to claim 18, wherein the amplified signal is substantially stable for variations in a power supply voltage provided to the power amplifier for powering thereof.

20. A method of controlling a power amplifier circuit according to claim 19, wherein a power of the amplified signal, specified using a logarithmic scales is proportional to the control voltage.

21. Method of temperature compensating an amplifier comprising the steps of:
providing a plurality of resistors within the amplifier circuit for each having a varied performance in response to changes in temperature;
providing a plurality of transistors within the amplifier circuit for each having a varied performance in response to changes in temperature; and,
varying a main bias current provided to the amplifier in dependence upon changes in temperature due to some of the plurality of resistors and some of the plurality of transistors, such that changes in amplifier performance and in the main bias current are varied, resulting in little or no change to an amplified version of the input signal in response to changes in temperature.
